(19) United States
(12) Patent Application Publication
(10) Pub. No.: US 2025/0046658 A1
(43) Pub. Date: Feb. 6, 2025

(54) SUBSTRATE PROCESSING METHOD AND SUBSTRATE PROCESSING APPARATUS

(71) Applicant: Tokyo Electron Limited, Tokyo (JP)

(72) Inventors: Hiroyuki KARASAWA, Yamanashi (JP); Masakazu YAMAMOTO, Iwate (JP); Yuichi TAKENAGA, Yamanashi (JP); Youngtai KANG, Tokyo (JP); Shota YAMAZAKI, Tokyo (JP)

(21) Appl. No.: 18/782,981

(22) Filed: Jul. 24, 2024

(30) Foreign Application Priority Data
Aug. 1, 2023 (JP) 2023-125406

(51) Int. Cl. H01L 21/66; C23C 16/46; C23C 16/52

(52) U.S. Cl. CPC H01L 22/26; C23C 16/46; C23C 16/52

(57) ABSTRACT

A substrate processing method includes providing a substrate processing apparatus including a processing container that accommodates a substrate, and a heater that heats an inside of the processing container; setting a specific section with an in-plane temperature distribution of a substrate that results in a desired outcome of substrate processing based on a first prediction model that predicts a time-dependent change of the in-plane temperature distribution of the substrate after temperature increase or decrease caused by the heater; and performing the substrate processing in the specific section.

### CROSS-REFERENCE TO RELATED APPLICATIONS

This application is based on and claims priority from Japanese Patent Application No. 2023-125406, filed on Aug. 1, 2023, with the Japan Patent Office, the disclosure of which is incorporated herein in its entirety by reference.

### TECHNICAL FIELD

The present disclosure relates to a substrate processing method and a substrate processing apparatus.

### BACKGROUND

Japanese Patent Publication No. 2002-043301 proposes controlling a heat treatment device using a set temperature profile that represents a relationship between the elapse of time and a set temperature. The set temperature profile used in controlling the heat treatment device is defined to include both a central high temperature state in which the temperature near the center portion of the substrate is in a high temperature state during film formation, and a peripheral edge high temperature state in which the temperature at the peripheral edge of the substrate is in a high temperature state during film formation.

### SUMMARY

According to an embodiment of the present disclosure, there is provided a substrate processing method, the method including: the method including: providing a substrate processing apparatus including: a processing container configured to accommodate a substrate, and a heater configured to heat an inside of the processing container; and (a) setting a specific section with an in-plane temperature distribution of the substrate that results in a desired outcome of a substrate processing based on a first prediction model that predicts a time-dependent change of the in-plane temperature distribution of the substrate after temperature increase or decrease by the heater; and (b) performing the substrate processing in the specific section.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional schematic diagram illustrating an example of a substrate processing apparatus according to an embodiment.

FIGS. 2A to 2D are diagrams illustrating an example of conventional temperature control during substrate processing.

FIGS. 3A and 3B are diagrams illustrating an example of simulation results of a temperature distribution in a substrate plane after the start of temperature increase.

FIG. 4 is a flowchart illustrating an example of a substrate processing method according to an embodiment.

FIG. 5 is a diagram illustrating an example of experimental results of a temperature distribution in a substrate plane after the start of temperature increase according to an embodiment.

FIG. 6 is a diagram illustrating an example of experimental results of a temperature distribution in a substrate plane after the start of temperature increase according to an embodiment.

FIGS. 7A to 7D are diagrams illustrating an example of a film thickness distribution in a substrate plane during a specific section according to an embodiment.

FIGS. 8A to 8D are diagrams illustrating an example of a film thickness distribution in a substrate plane during a specific section according to an embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### [Substrate Processing Apparatus]

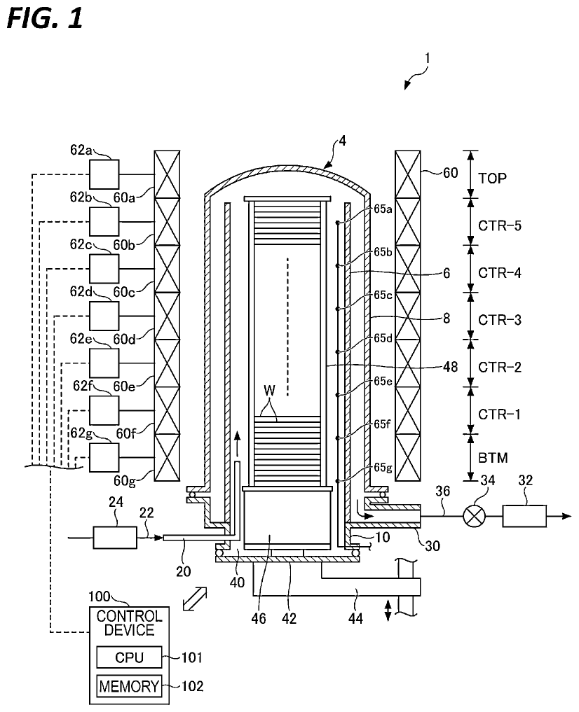

FIG. 1 illustrates a substrate processing apparatus 1 according to an embodiment, which is capable of executing a substrate processing method to be described later. FIG. 1 is a cross-sectional schematic diagram illustrating an example of the substrate processing apparatus 1 according to an embodiment. The substrate processing apparatus 1 according to the present embodiment includes a substantially cylindrical processing container 4 with the longitudinal direction thereof oriented vertically. The processing container 4 has a double tube structure including an inner cylinder 6 in the form of a cylindrical body, and an outer cylinder 8 including a ceiling which is concentrically arranged outside the inner cylinder 6. However, the substrate processing apparatus 1 may also have a single tube structure with a single cylindrical body. The inner cylinder 6 and the outer cylinder 8 are made of, for example, a heat-resistant material such as quartz. Substrate processing such as film formation is performed on a plurality of substrates W inside the processing container 4.

The inner cylinder 6 and the outer cylinder 8 are held at lower ends thereof by a manifold 10, which is made of, for example, stainless steel. The manifold 10 is fixed to a base plate (not illustrated), for example. Since the manifold 10 forms a substantially cylindrical internal space together with the inner cylinder 6 and the outer cylinder 8, the manifold 10 is regarded as forming a part of the processing container 4.

The processing container 4 includes the inner and outer cylinders 6 and 8 made of, for example, a heat-resistant material such as quartz, and the manifold 10 made of, for example, stainless steel. The manifold 10 is provided at the lower side of a sidewall of the processing container 4 to hold the inner and outer cylinders 6 and 8 from below.

The manifold 10 includes a gas introducer 20 for introducing a process gas used for substrate processing into the processing container 4. FIG. 1 illustrates a form in which one gas introducer 20 is provided, but is not limited thereto, and a plurality of gas introducers 20 may be provided depending on, for example, the type of gases used.

An introduction pipe 22 is connected to the gas introducer 20 to introduce the process gas into the processing container 4. A flow rate regulator 24 such as a mass flow controller for regulating the gas flow rate, a valve (not illustrated), and the like, are interposed in the introduction pipe 22.

Further, the manifold 10 includes a gas exhauster 30 for exhausting the inside of the processing container 4. An exhaust pipe 36 is connected to the gas exhauster 30 and includes a vacuum pump 32 capable of controlling a pressure reduction inside the processing container 4, an opening-degree variable valve 34, and the like.

A furnace opening 40 is formed at a lower end of the manifold 10, and a disc-shaped lid 42, which is made of, for example, stainless steel, is provided at the furnace opening 40. The lid 42 is provided to be vertically movable by a lifting mechanism 44 that functions as a boat elevator, for example, and the lid 42 is configured to provide an airtight seal of the furnace opening 40.

A thermal insulation tube 46, which is made of, for example, quartz, is installed on the lid 42. A wafer boat 48, which is made of, for example, quartz, is placed on the thermal insulation tube 46 to hold, for example, approximately 50 to 200 substrates W horizontally at predetermined sections in multiple stages. These substrates W arranged in the wafer boat 48 constitute a single batch and are subjected to various substrate processings on a batch-by-batch basis. An example of the substrates W may be wafers with a diameter ranging from 200 mm to 300 mm. The wafer boat 48 is an example of a boat that holds a plurality of substrates in a plurality of slots arranged vertically in multiple stages and that is loaded into and unloaded from the processing container 4.

The wafer boat 48 is loaded into the processing container 4 by moving the lid 42 upward using the lifting mechanism 44, and the substrates W held in the wafer boat 48 are subjected to a substrate processing. After the substrate processing is performed, the wafer boat 48 is unloaded from the processing container 4 to a lower loading area by moving the lid 42 downward using the lifting mechanism 44.

A heater 60, which has, for example, a cylindrical shape, is provided at the outer peripheral side of the processing container 4 and is capable of heating the processing container 4 to a predetermined temperature. The heater 60 is an example of a heater used to heat the inside of the processing container 4. The heater 60 includes a plurality of heaters 60a to 60g for adjusting the temperature of the plurality of substrates W, which are accommodated inside the processing container 4 for each of a plurality of zones.

The heaters 60a to 60g are provided from top to bottom in the vertical direction. The heaters 60a to 60g are configured to enable the heater output values (power, heat generation amount) to be independently controlled by their respective power controllers 62a to 62g. Further, temperature sensors 65a to 65g are installed inside the inner cylinder 6 to correspond to the heaters 60a to 60g. The temperature sensors 65a to 65g are provided from top to bottom in the vertical direction of the inner cylinder 6. Examples of the temperature sensors 65a to 65g may include thermocouples and resistance temperature detectors. The temperature sensors 65a to 65g are also collectively referred to as “temperature sensor 65.”

When dividing an area of the wafer boat 48, where the substrates are accommodated, into a plurality of zones, the heaters 60a to 60g are provided for each zone in a one-to-one correspondence. In the substrate processing apparatus 1, for example, the wafer boat 48 is divided into seven zones. The seven zones are referred to as “BTM,” “CTR-1,” “CTR-2,” “CTR-3,” “CTR-4,” “CTR-5,” and “TOP” in order from bottom.

The heater 60a heats a plurality of substrates in the “TOP” zone. The temperature sensor 65a measures the temperature of the “TOP” zone inside the inner cylinder 6. Hereinafter, the temperature of each zone inside the inner cylinder 6 is also simply referred to as “zone temperature.” The heater 60b heats a plurality of substrates in the “CTR-5” zone. The temperature sensor 65b measures the temperature of the “CTR-5” zone. The heater 60c heats a plurality of substrates in the “CTR-4” zone. The temperature sensor 65c measures the temperature of the “CTR-4” zone. The heater 60d heats a plurality of substrates in the “CTR-3” zone. The temperature sensor 65d measures the temperature of the “CTR-3” zone. The heater 60e heats a plurality of substrates in the “CTR-2” zone. The temperature sensor 65e measures the temperature of the “CTR-2” zone. The heater 60f heats a plurality of substrates in the “CTR-1” zone. The temperature sensor 65f measures the temperature of the “CTR-1” zone. The heater 60g heats a plurality of substrates in the “BTM” zone. The temperature sensor 65g measures the temperature of the “BTM” zone.

A control device 100 controls an overall operation of the substrate processing apparatus 1. The control device 100 includes a Central Processing Unit (CPU) 101 and a memory 102. The CPU 101 is a computer for controlling the overall operation of the substrate processing apparatus 1.

The memory 102 stores a control program for realizing the substrate processing executed in the substrate processing apparatus 1 under the control of the control device 100 and a recipe that sets a substrate processing sequence, and the like, for each step. Further, the memory 102 stores various programs for causing each component of the substrate processing apparatus 1 to execute the substrate processing according to a process condition set in the recipe. These various programs may be stored in storage media and then be stored in the memory 102. Examples of the storage media may include hard disks, semiconductor memories, and portable media such as CD-ROMs, DVDs, and flash memories. Further, these programs, parameters, and various data may be transmitted appropriately to the memory 102 from other devices or host computers via wired or wireless communication methods. The control device 100 may be a control device provided separately from the substrate processing apparatus 1. Further, the memory 102 may be a storage device provided separately from the substrate processing apparatus 1.

The temperature sensors 65a to 65g transmit detection signals to the control device 100. The control device 100 calculates setting values of the power controllers 62a to 62g based on the detection signals from the temperature sensors 65a to 65g, and outputs the calculated setting values to the respective power controllers 62a to 62g. This enables the independent control of output values (Power) for the heaters 60a to 60g.

### [Conventional Temperature Control]

In the substrate processing apparatus 1 in which substrate processing is performed on a batch-by-batch basis, there is a problem of non-uniform distribution (e.g., film thickness distribution) of substrate processing results in a substrate plane due to factors such as the flow of raw material gases and microstructures on the substrate. In order to address these issues, a technology known as Time-Varying Setpoint (TVS) has been conventionally used.

When the flow rates of gases supplied into the processing container 4 and the pressure inside the processing container 4 are equal, temperature becomes a dominant factor in determining a film formation rate. TVS utilizes a temperature difference occurring in a substrate plane during temperature increase or decrease to perform film formation during temperature increase or decrease, in order to achieve a uniform film thickness distribution in a substrate plane. Further, TVS includes a technology to obtain optimal temperature increase/decrease conditions based on previously measured film thickness distributions. In TVS, a statistical model that predicts temperatures at the center and edge (peripheral edge) of the substrate is used to calculate a ramping rate (temperature increase/decrease rate) and a film formation time that result in a uniform film thickness in a substrate plane.

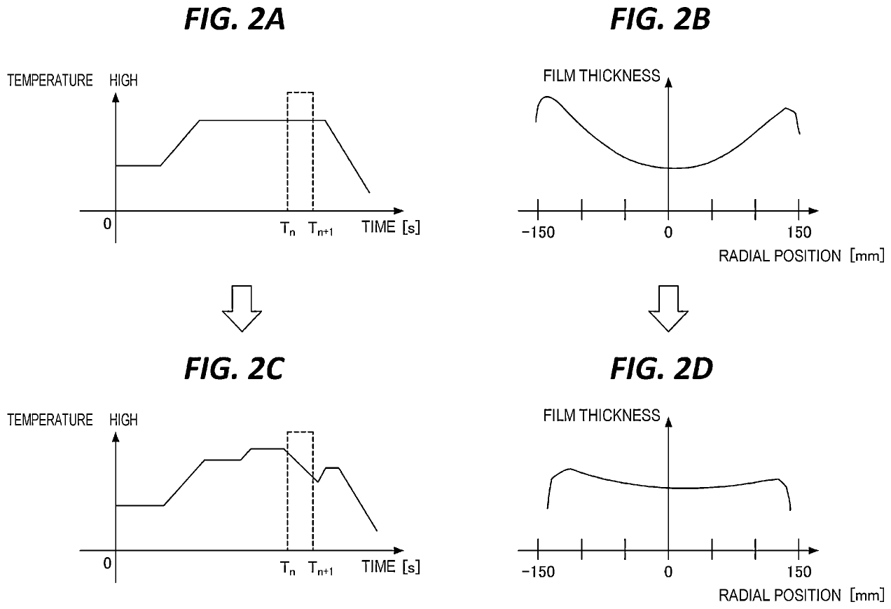

FIG. 2A is a diagram illustrating an example of control temperature setting before film thickness adjustment by TVS, where film formation is performed while controlling the heater 60 to achieve a consistent control temperature represented on the vertical axis during a section Tₙ˜Tₙ₊₁ represented on the horizontal axis. FIG. 2B is a diagram illustrating the resulting film thickness distribution in a wafer plane, as represented on the vertical axis with respect to radial positions on a wafer with a diameter of 300 mm represented on the horizontal axis. On the horizontal axis, “0” represents the center of a wafer, and “150 mm” and “−150 mm” represent the outermost end of the wafer. The film thickness distribution in a wafer plane exhibits a thicker peripheral edge of the wafer slightly inward of the wafer outermost end and a thinner wafer center.

To avoid film formation with an M-shaped radial film thickness distribution in a wafer plane due to gas flow imbalances and other factors, FIG. 2C illustrates film thickness adjustment using TVS. In other words, film formation is performed by controlling the heater 60 to decrease the temperature at a constant rate during a section Tₙ˜Tₙ₊₁ in FIG. 2C. This keeps the temperature at the wafer center high while cooling the wafer edge, resulting in a higher film formation rate at the wafer center compared to the wafer edge. This improves the in-plane uniformity of film thickness from the center to the edge of the wafer, as illustrated in FIG. 2D.

However, although the uniformity of a film thickness distribution in a wafer plane is improved, there are only two adjustment targets: the film thickness at the center and the film thickness at the edge. Therefore, even with the use of TVS, a process condition that results in the M-shaped film thickness distribution as illustrated in FIG. 2B when not using TVS has limitations in adjusting the in-plane uniformity of film thickness, resulting in a slightly thicker film thickness at the edge, as illustrated in FIG. 2D.

In other words, in conventional TVS, film formation begins at a timing when a certain time has elapsed after the start of temperature increase or decrease by the heater 60. Therefore, a temperature distribution in a wafer plane at the center, the edge, and the middle between the center and the edge has a similar curve shape regardless of the elapsed time from the start of temperature increase or decrease. This limits the degree of freedom in adjustment to just two degrees; the slope and intercept of a line approximating the curve. Therefore, since the degree of freedom in adjusting the film thickness distribution of the wafer is also limited to two degrees, when attempting to uniformize a film thickness distribution in a wafer plane by adjusting a complex film thickness distribution shape, it may result in the inability to achieve uniformity.

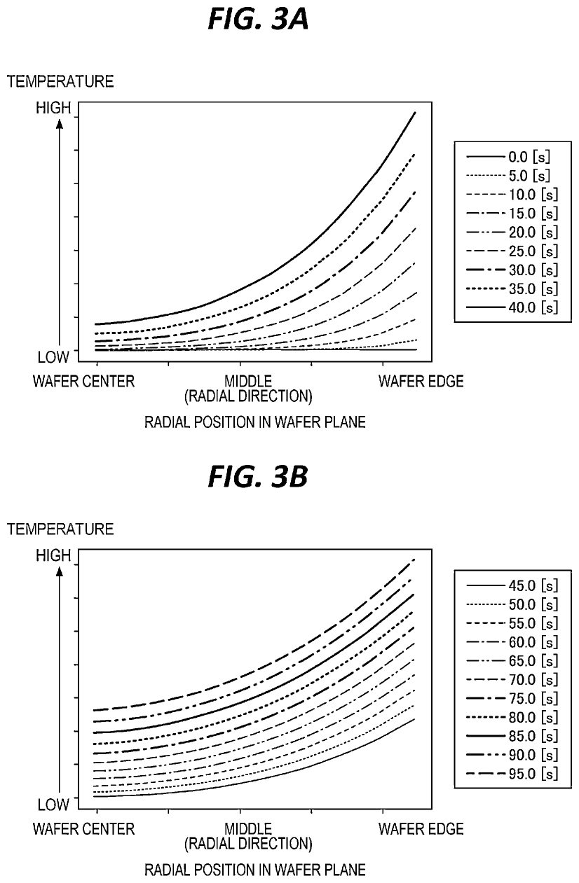

FIGS. 3A and 3B illustrate an example of simulation results of a temperature distribution in a substrate plane after the start of temperature increase inside the processing container 4. Assuming the start of temperature increase is at 0.0 seconds and the elapsed time from the start of temperature increase is measured at 5-second intervals, FIG. 3A illustrates an example of simulation results of a temperature distribution at radial positions in a wafer plane at 5-second intervals from 0.0 to 40.0 seconds (immediately after the start of temperature increase), and FIG. 3B illustrates an example of simulation results of a temperature distribution at radial positions in a wafer plane at 5-second intervals from 45.0 to 95.0 seconds (a certain time after the start of temperature increase). In FIGS. 3A and 3B, the left end of the horizontal axis represents the wafer center, the right end represents the wafer edge, and the middle represents the radial middle between the wafer center and the wafer edge.

In conventional TVS, film formation begins at a timing when a certain time has elapsed after the start of temperature increase or decrease. Therefore, as illustrated in FIG. 3B, since temperature distributions (curves) in a wafer plane at all the elapsed time intervals (from 45.0 seconds to 95.0 seconds) after the start of temperature increase exhibit a similar shape, the degree of freedom in adjusting the film thickness distribution is low.

In contrast, as illustrated in FIG. 3A, when performing film formation at intervals from 0.0 seconds to 10.0 seconds after the start of temperature increase, there is almost no temperature difference between the wafer center and the radial middle. On the other hand, when performing film formation at intervals from 15.0 seconds to 40.0 seconds after the start of temperature increase, there occurs a temperature difference between the wafer center, the radial middle, and the wafer edge. In other words, a rich variation in the temperature distribution (curve shape) in a wafer plane immediately after the start of temperature increase allows for a higher degree of freedom in adjusting the film thickness distribution. Various temperature patterns appear at different times immediately after the start of temperature increase or decrease since heat is transferred in a wafer plane through heat conduction.

Therefore, while temperature control using conventional TVS utilized the section where the in-plane temperature difference began to stabilize for film formation, the substrate processing method according to the present embodiment also utilizes the section with a complex temperature distribution immediately after the start of temperature increase or decrease for film formation.

By using the complex temperature distribution immediately after the start of temperature increase or decrease, it is possible to perform film formation with a film thickness distribution corresponding to a rich variation in the temperature distribution, allowing for the adjustment of the film thickness distribution with three or more degrees of freedom. In other words, it is possible to adjust temperature control conditions including the section immediately after the start of temperature increase or decrease. This allows for targeting and creating a film thickness distribution that has not been achieved. Accordingly, it is possible to adjust a complex in-plane distribution that has not been adjusted, and to improve the in-plane uniformity of a film thickness distribution.

### [Prediction Model]

In the substrate processing method according to the present embodiment, a specific section with a temperature distribution in a substrate plane that results in a desired substrate processing outcome is set based on a first prediction model that predicts a time-dependent change of the temperature distribution in a substrate plane after temperature increase or decrease by the heater 60. Then, substrate processing is performed during the specific section after temperature increase or decrease by the heater 60.

The first prediction model may be predefined by the temperature sensor 65 based on detected results of a temperature in a substrate plane that is changed after temperature increase or decrease by the heater 60. The first prediction model may also be derived based on a physical model created using equations that describe physical laws such as heat conduction equations. The first prediction model predicts a temperature in a substrate plane based on a temperature setting curve.

A second prediction model predicts a substrate processing outcome based on a temperature distribution in a substrate plane during substrate processing under a predetermined process condition. In the substrate processing method according to the present embodiment, a temperature distribution in a substrate plane that results in a desired outcome distribution in a substrate plane of substrate processing performed under a predetermined process condition is predicted based on the second prediction model.

### [Substrate Processing Method]

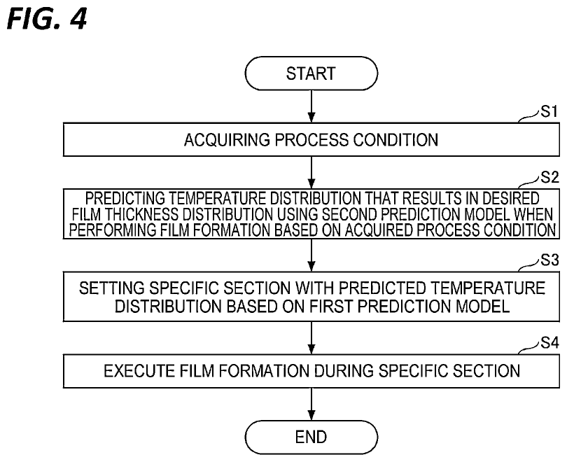

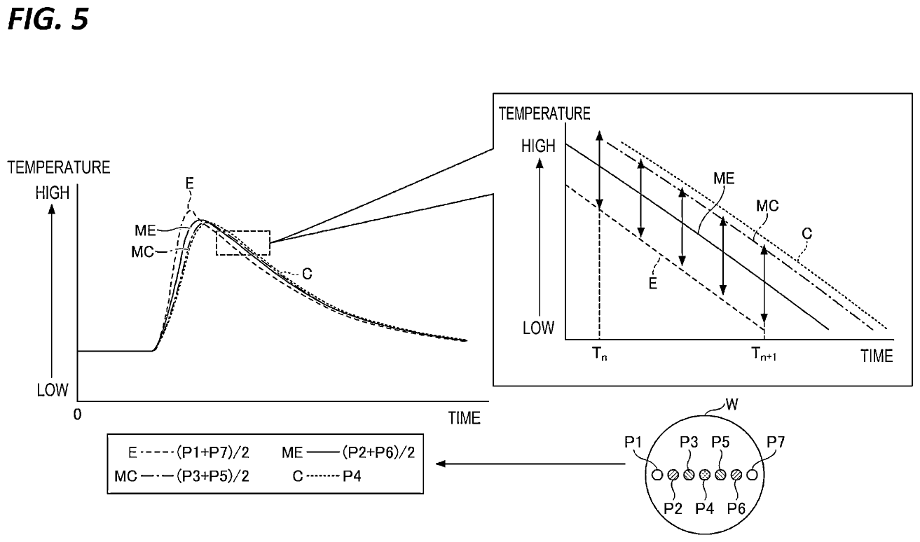

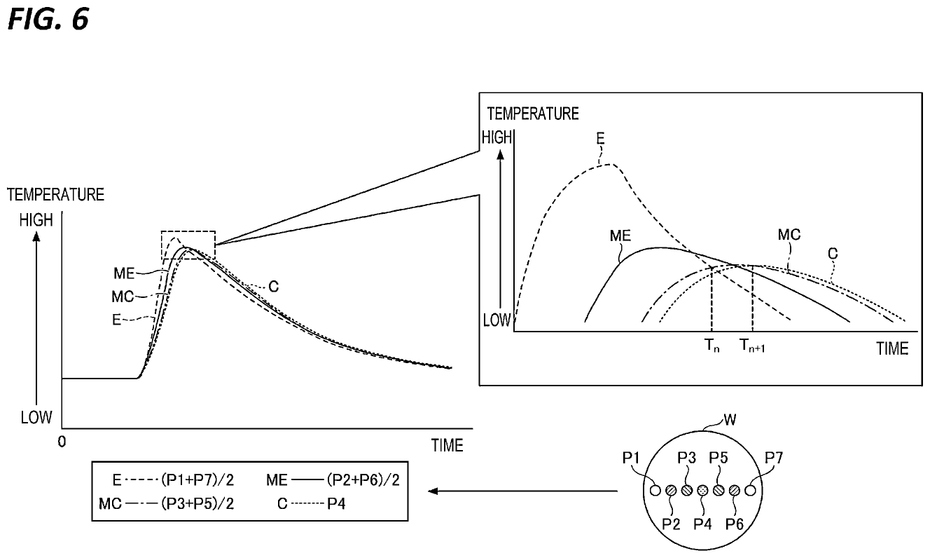

An example of the substrate processing method according to the present embodiment will be described with reference to FIGS. 4 to 6. FIG. 4 is a flowchart illustrating an example of a substrate processing method according to an embodiment. FIGS. 5 and 6 are diagrams illustrating an example of experimental results of a temperature distribution in a substrate plane after the start of temperature increase according to an embodiment. In FIG. 4, film formation is be described as an example of substrate processing. The substrate processing method is controlled by the control device 100 and is executed by the substrate processing apparatus 1.

In step S1, the control device 100 acquires a process condition from a recipe used for film formation.

In step S2, the control device 100 uses the second prediction model to predict a temperature distribution in a substrate plane that results in a desired film thickness distribution in a substrate plane when performing film formation based on the acquired process condition.

In step S3, the control device 100 uses the first prediction model to set a specific section with the temperature distribution in a substrate plane predicted in step S2.

In step S4, the control device 100 executes film formation during the specific section after the start of temperature increase or decrease control by the heater 60, and completes this processing.

The left graphs in FIGS. 5 and 6 illustrate a time-dependent change in the measurement results of the substrate temperature at seven measurement points provided in the radial direction in the plane of the substrate W (See measurement points P1 to P7 in the substrate W) after the boat 48 has been loaded into the processing container 4.

The left graphs in FIGS. 5 and 6 are identical, and the first prediction model is defined based on the time-dependent change in the measurement results of the substrate temperature at these measurement points.

In the graphs, curve E represents a time-dependent change in the average value [(P1+P7)/2] of the measured temperatures at P1 and P7, which correspond to the substrate edge, among the seven measurement points in the radial direction of the substrate W. Curve ME represents a time-dependent change in the average value [(P2+P6)/2] of the measured temperatures at P2 and P6, which correspond to the middle (at the radial outer side). Curve MC represents a time-dependent change in the average value [(P3+P5)/2] of the measured temperatures at P3 and P5, which correspond to the middle (at the radial inner side). Curve C represents a time-dependent change in the measured temperature at P4, which corresponds to the substrate center.

The enlarged graphs in FIGS. 5 and 6 are enlargements of the sections surrounded by dotted lines in the left graphs. The boat 48 is completely loaded into the processing container 4 at 0 seconds on the horizontal axis of the left graphs in FIGS. 5 and 6, and thereafter, the heater 60 is turned on in response to a temperature increase instruction in a step of the recipe to increase the temperature inside the processing container 4.

When a section Tₙ˜Tₙ₊₁ as illustrated in the enlarged graph of FIG. 5 is set as the specific section in step S3 and TVS, which begins film formation at a timing when a certain time has elapsed after the start of temperature increase, is used, a temperature difference in a substrate plane does not significantly change. According to this, the degree of freedom in adjusting the film thickness distribution is low, and it is not possible to perform adjustment with a high degree of freedom, such as increasing the film thickness only at the edge, only at the middle, or only at the center.

In a case of the temperature distribution in FIG. 5, since the temperature of curve C is highest, followed by curve MC, curve ME, and curve E in order, the film thickness distribution may be adjusted so that the film thickness is thickest at the center and becomes progressively thinner toward the middle (at the inner side), the middle (at the outer side), and the edge.

In contrast, when a section Tₙ˜Tₙ₊₁ surrounded by the dotted line in FIG. 6, as illustrated in the enlarged graph of FIG. 6, where the temperature immediately after the start of temperature increase is switched from temperature increase to temperature decrease, is set as the specific section in step S3, a temperature difference in a substrate plane significantly changes. According to this, the degree of freedom in adjusting the film thickness distribution is high, and it is possible to perform adjustment with a high degree of freedom, such as increasing the film thickness only at the edge, only at the middle, or only at the center.

For example, in the section Tₙ˜Tₙ₊₁ of FIG. 6, the film thickness distribution may be adjusted so that the film thickness is thicker at the middle and thinner at the center and the edge since the temperature at the middle (curves ME and MC) is higher than the temperature at the center (curve C) and the edge (curve E). Further, the film thickness may be increased only at the edge by setting a section where the temperature at the edge (curve E) is high, as the specific section and performing film formation during this section.

As described above, a specific section is set based on the first prediction model to have a temperature distribution in a substrate plane that results in a desired film thickness distribution in a substrate plane when performing film formation based on the process condition. Then, film formation is performed during the specific section.

By setting the specific section from a timeslot after temperature increase or decrease by the heater 60 and before a temperature difference in a substrate plane stabilizes, it is possible to increase the degree of freedom in adjusting the film thickness distribution.

### [Simulation Results of Film Thickness Distribution Adjustment]

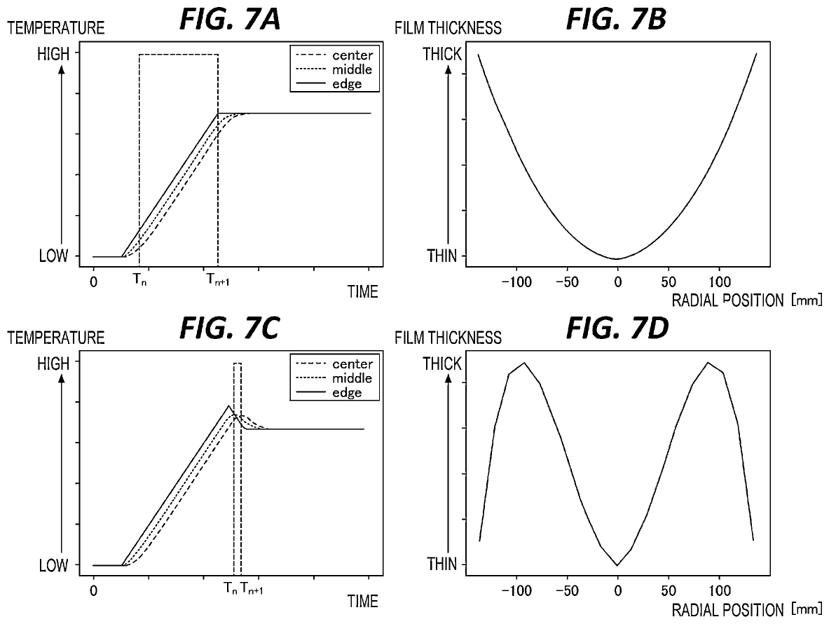

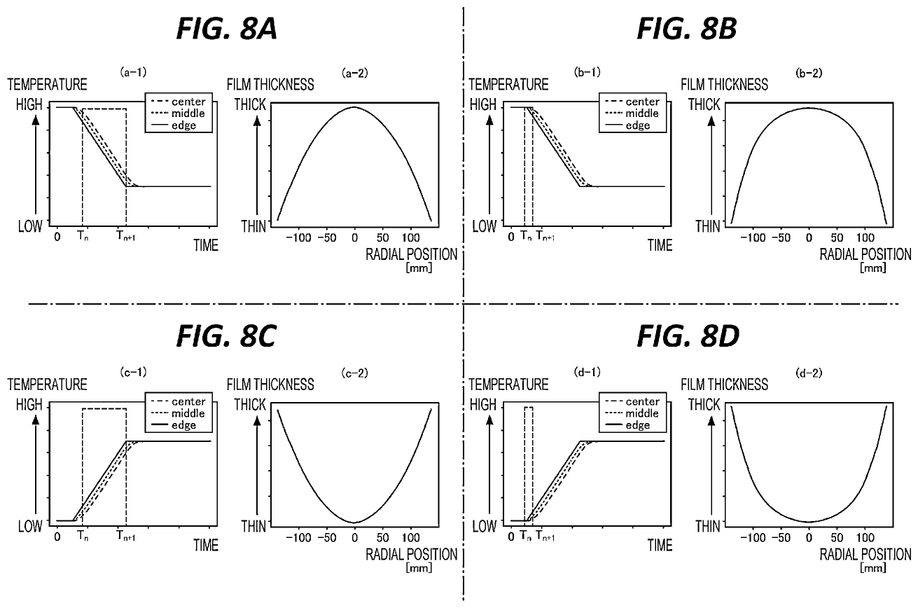

The results of simulating film thickness distribution adjustment are described with reference to FIGS. 7A to 7D and 8A to 8D. FIGS. 7A to 7D and 8A to 8D are diagrams illustrating an example of a film thickness distribution in a substrate plane during a specific section according to an embodiment.

### (Simulation 1)

In an example illustrated in FIG. 7A, film formation is performed during a specific section Tₙ˜Tₙ₊₁ of temperature increase after a temperature difference in a substrate plane stabilizes within a certain time (e.g., several tens of seconds) after the start of temperature increase control by the heater 60. According to this, during the section Tₙ˜Tₙ₊₁, the control temperature is highest at the edge, followed by the middle, and then the center of the substrate. As illustrated in FIG. 7B, the edge becomes thicker and the center becomes thinner, resulting in a concave film thickness distribution. This temperature control may improve the uniformity of a film thickness distribution in a substrate plane in a case where the film thickness distribution tends to be convex (mountain-shaped) while maintaining a constant control temperature during film formation.

### (Simulation 2)

In an example illustrated in FIG. 7C, film formation is performed during a specific section Tₙ˜Tₙ₊₁ at a timing of switching from temperature increase to temperature decrease after the start of temperature increase control by the heater 60. According to this, during the section Tₙ˜Tₙ₊₁, the control temperature is higher at the middle of the substrate, compared to the edge and the center. As illustrated in FIG. 7D, the middle becomes thicker and the edge and the center becomes thinner, resulting in an M-shaped film thickness distribution. This temperature control may improve the uniformity of a film thickness distribution in a substrate plane in a case where the film thickness distribution tends to be W-shaped while maintaining a constant control temperature during film formation. To increase the film thickness, it is necessary to achieve a temperature distribution where a temperature distribution pattern repeatedly appears during the section Tₙ˜Tₙ₊₁ as illustrated in FIG. 7C.

The temperature control illustrated in FIG. 7A is executed using TVS. Temperature control illustrated in FIG. 7C is executed using the substrate processing method according to the present embodiment. According to the substrate processing method of the present embodiment, film formation is performed using a temperature distribution at a switching timing between temperature increase and temperature decrease. This enables the creation of a complex film formation distribution such as an M-shaped distribution. Although the described substrate processing method according to the present embodiment does not include TVS, the substrate processing method according to the present embodiment may incorporate TVS to execute temperature control in combination with TVS.

### (Simulation 3)

In an example illustrated in (a-1) of FIG. 8A, film formation is performed during a specific section Tₙ˜Tₙ₊₁ of temperature decrease after a temperature difference in a substrate plane stabilizes within a certain time (e.g., several tens of seconds) after the start of temperature decrease control by the heater 60. According to this, during the section Tₙ˜Tₙ₊₁, the control temperature is highest at the center, followed by the middle, and then the edge of the substrate. As illustrated in (a-2) of FIG. 8A, the center becomes thicker and the edge becomes thinner, resulting in a convex film thickness distribution. This temperature control may improve the uniformity of a film thickness distribution in a substrate plane in a case where the film thickness distribution tends to be concave while maintaining a constant control temperature during film formation.

The temperature control in (c-1) of FIG. 8C is the same as the temperature control in FIG. 7A, and the film thickness distribution in (c-2) of FIG. 8C is the same as the film thickness distribution in FIG. 7B. The film thickness distribution in (a-2) of FIG. 8A is the inverted form of the film thickness distribution in (c-2) of FIG. 8C.

### (Simulation 4)

In an example illustrated in (b-1) of FIG. 8B, a timing immediately after the start of temperature decrease control by the heater 60 is set to a specific section Tₙ˜Tₙ₊₁, and film formation is performed during the section Tₙ˜Tₙ₊₁. According to this, during the section Tₙ˜Tₙ₊₁, the control temperature is highest at the center, followed by the middle, and then the edge of the substrate. Further, a temperature difference between the center, the middle, and the edge of the substrate is not constant, with the edge exhibiting the fastest temperature decrease and the center exhibiting the slowest temperature decrease. As illustrated in (b-2) of FIG. 8B, the center becomes thicker and the edge becomes thinner, resulting in a U-shaped film thickness distribution. This temperature control may improve the uniformity of a film thickness distribution in a substrate plane in a case where the film thickness distribution tends to be inverted U-shaped while maintaining a constant control temperature during film formation. To increase the film thickness, it is necessary to achieve a temperature distribution where a temperature distribution pattern repeatedly appears during the section Tₙ˜Tₙ₊₁ as illustrated in (b-1) of FIG. 8B.

### (Simulation 5)

In an example illustrated in (d-1) of FIG. 8D, a timing immediately after the start of temperature increase control by the heater 60 is set to a specific section Tₙ˜Tₙ₊₁, and film formation is performed during the section Tₙ˜Tₙ₊₁. According to this, during the section Tₙ˜Tₙ₊₁, the control temperature is highest at the edge, followed by the middle, and then the center of the substrate. Further, a temperature difference between the edge, the middle, and the center of the substrate is not constant, with the edge exhibiting the fastest temperature increase and the center exhibiting the slowest temperature increase. As illustrated in (d-2) of FIG. 8D, the edge becomes thicker and the center becomes thinner, resulting in an inverted U-shaped film thickness distribution. This temperature control may improve the uniformity of a film thickness distribution in a substrate plane in a case where the film thickness distribution tends to be U-shaped while maintaining a constant control temperature during film formation. To increase the film thickness, it is necessary to achieve a temperature distribution where a temperature distribution pattern repeatedly appears during the section Tₙ˜Tₙ₊₁ as illustrated in (d-1) of FIG. 8D.

### [Zone Control]

The substrate processing apparatus 1 may have a different film thickness distribution for each zone. Therefore, temperature control in the substrate processing method according to the present embodiment may be performed for each zone. In this case, when dividing the plurality of slots of the boat 48 into several zones, the first prediction model predicts a time-dependent change of the temperature distribution in a substrate plane after temperature increase or decrease by the heater 60 for each zone. The control device 100 may set a specific section with a temperature distribution in a substrate plane that results in a desired substrate processing outcome for each zone based on the first prediction model.

As described above, according to the substrate processing method and substrate processing apparatus of the present embodiment, it is possible to increase the degree of freedom in adjusting a processing outcome distribution in a substrate plane.

According to this substrate processing method, a substrate temperature distribution immediately after substrate temperature decrease or increase is set to a specific section, and film formation is performed during the specific section. Thus, a complex film thickness distribution such as a U-shaped or W-shaped distribution, which has not been fully adjusted with conventional TVS, may be approximated to a uniform distribution, which improves the in-plane uniformity of substrate processing such as film formation. For example, film thickness distributions in the radial direction may be convex, concave, W-shaped, or M-shaped depending on process conditions. In contrast, according to the substrate processing method of the present embodiment, a uniform film thickness distribution may be achieved by performing film formation with a film thickness distribution that cancels out these complex film thickness distributions.

For example, a process condition, under which substrate processing is performed, is acquired, and film formation is performed under the acquired process condition. In this case, an outcome of substrate processing under the acquired process condition is predicted based on the second prediction model that predicts a substrate processing outcome from a temperature distribution in a substrate plane during substrate processing performed under a predetermined process condition. Then, a temperature distribution in a substrate plane that cancels out the predicted substrate processing outcome is predicted. Next, a section with the predicted temperature distribution in a substrate plane is set to a specific section based on the first prediction model, and substrate processing is performed during the specific section under the process condition. Thus, a uniform film thickness distribution may be achieved by performing film formation with a film thickness distribution that cancels out a film thickness distribution obtained when maintaining a constant control temperature during normal film formation.

Thus, it becomes possible to perform film formation with a film thickness distribution that corresponds to a temperature distribution during a specific section, allowing for film thickness distribution adjustment with three or more degrees of freedom. To calculate a ramping rate (temperature increase or decrease rate) or a film formation period, it is necessary to be able to predict a temperature distribution in a substrate plane immediately after the start of temperature increase or decrease using the first prediction model such as a simulation model, a calculation formula, or an experimental model.

In the above embodiments, the substrate processing apparatus according to the present embodiment has been described as a batch type film forming apparatus that processes a plurality of substrates simultaneously, but the present disclosure is not limited to this. The substrate processing apparatus according to the present embodiment may also be a single wafer type film forming apparatus that processes wafers one by one. Further, the substrate processing apparatus may be a semi-batch type film forming apparatus that revolves, by a rotary table, a plurality of wafers placed on the rotary table inside a processing container to sequentially pass the wafers through a region where a first gas is supplied and a region where a second gas is supplied for wafer processing. Further, the substrate processing apparatus may be a multi-wafer type film forming apparatus provided with a plurality of placement tables inside a single processing container.

According to one aspect, it is possible to increase the degree of freedom in adjusting the distribution of processing results in a substrate plane.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
providing a substrate processing apparatus including:
a processing container configured to accommodate a substrate, and
a heater configured to heat an inside of the processing container;
(a) setting a specific section with an in-plane temperature distribution of the substrate that results in a desired outcome of a substrate processing based on a first prediction model that predicts a time-dependent change of the in-plane temperature distribution of the substrate after temperature increase or decrease by the heater; and
(b) performing the substrate processing in the specific section.

2. The substrate processing method according to claim 1, wherein the substrate processing apparatus includes a boat configured to hold a plurality of substrates in a plurality of slots arranged vertically thereon in multiple stages, the boat capable of being loaded into and unloaded from the processing container, and
wherein when the plurality of slots are divided into several zones, (a) includes setting, for each zone, the specific section with the in-plane temperature distribution in the substrate that results in the desired outcome of the substrate processing based on the first prediction model that predicts the time-dependent change of the in-plane temperature distribution of the substrate for each zone after temperature increase or decrease by the heater.

3. The substrate processing method according to claim 1, further comprising:
(c) acquiring a process condition under which the substrate processing is performed; and
(d) predicting an outcome of a substrate processing performed under the process condition acquired in (c) based on a second prediction model that predicts an outcome of the substrate processing from an in-plane temperature distribution of the substrate during a substrate processing performed under a predetermined process condition, and predicting an in-plane temperature distribution of the substrate that cancels out the predicted outcome of the substrate processing,
wherein (a) includes setting, as the specific section, a section with the predicted in-plane temperature distribution of the substrate based on the first prediction model, and
(b) includes performing the substrate processing based on the process condition in the specific section.

4. The substrate processing method according to claim 1, wherein (a) includes setting the specific section included in a time period after temperature increase or decrease by the heater and before a temperature difference between a center, a radial middle, and an edge in a substrate plane becomes stable.

5. The substrate processing method according to claim 1, wherein the substrate processing apparatus further includes a plurality of temperature sensors installed in a radial direction of the substrate, and
the first prediction model is defined in advance based on a result of detecting an in-plane temperature in a substrate that is changed after temperature increase or decrease by the heater, using the plurality of temperature sensors.

6. The substrate processing method according to claim 3, wherein the substrate processing is film formation,
(a) includes setting the specific section based on the first prediction model to have an in-plane temperature distribution of a substrate that results in a desired film thickness distribution in a substrate plane when performing the film formation based on a process condition under which the substrate processing is performed, and
(b) includes performing the film formation in the specific section after temperature increase or decrease caused by the heater.

7. The substrate processing method according to claim 2, wherein the first prediction model is defined in advance based on a result of detecting an in-plane temperature of the substrate for each zone that is changed after temperature increase or decrease caused by the heater, using a plurality of temperature sensors installed for each zone.

8. A substrate processing apparatus comprising:
a processing container configured to accommodate a substrate;
a heater configured to heat an inside of the processing container; and
a controller,
wherein the controller controls the substrate processing apparatus to execute a process including:
(a) setting a specific section with an in-plane temperature distribution of a substrate that results in a desired outcome of a substrate processing based on a first prediction model that predicts a time-dependent change of the in-plane temperature distribution of the substrate after temperature increase or decrease caused by the heater; and
(b) performing the substrate processing in the specific section.
